(19) United States
(12) Patent Application Publication
(10) Pub. No.: US 2021/0025578 A1
(43) Pub. Date: Jan. 28, 2021

(54) LIGHT EMITTING DIODE LAMPS INCLUDING G8 LAMPS

(71) Applicant: Gardenia Industrial Limited, Tsimshatsui (HK)

(72) Inventor: Wei Lin Chen, Zhongshan (CN)

(21) Appl. No.: 16/773,475

(22) Filed: Jan. 27, 2020

(30) Foreign Application Priority Data
Jul. 27, 2019 (CN) 201921194462.6

(51) Int. Cl. F21V 29/10; F21V 23/00; H05K 1/02; H05K 1/18; H05K 1/05; F21V 23/06; F21V 29/89; F21V 29/70

(52) U.S. Cl. CPC F21V 29/10; F21V 23/005; H05K 1/0204; H05K 1/181; F21Y 2115/10; F21V 23/06; F21V 29/89; F21V 29/70; H05K 1/05

(57) ABSTRACT

A light emitting diode (LED) lamp includes: a housing; an thermally-conductive circuit board mounted inside the housing; a plurality of light emitting diodes (LEDs) mounted on the thermally-conductive circuit board; a plurality of pins arranged in the housing and electrically connected to the thermally-conductive circuit board; and a driving circuit mounted on the thermally-conductive circuit board, the driving circuit including a first heat-generating electronic element and a second heat-generating electronic element located on opposite surfaces of the thermally-conductive circuit board.

### CROSS-REFERENCE TO RELATED APPLICATION(S)

This application claims priority to Chinese Patent Application No. 201921194462.6 filed with the National Intellectual Property Administration of the People's Republic of China on Jul. 27, 2019, the entire disclosure of which is incorporated by reference herein.

### FIELD

Aspects of embodiments of the present disclosure relate to the field of light illumination, including light emitting diode (LED) lamps or light bulbs with a bi-pin base, such as a G8 type LED lamp.

### BACKGROUND

With the development and demand of solid-state lighting technology such as light emitting diode based lighting technology, lighting products have been widely used in many areas, such as lighting for hotels, lighting for product display, lighting for high-end leisure venues, and the like. For example, light emitting diode (LED) lamps, including lamps with bi-pin bases such as G8 type LED lamps, have been widely used in lighting for home wardrobes and in decorative illumination lamps for home cabinets.

However, comparative LED lamps on the market generally have large heat generation and short service life. Due to in part to their small size, comparative LED lamps (e.g., G8 type LED lamps) typically have poor heat dissipation. As a result, when the lamp is turned on for a relatively long period of time, the temperature inside the lamp becomes high, which may damage the lamp (e.g., damage the driving circuitry within the lamp). In addition, the poor heat dissipation function and resulting high working temperature of small LED lamps motivates the use of chip capacitors (e.g., surface mount chip capacitors). However, chip capacitors have limited capacitance (e.g., are constrained to relatively low capacitances), and therefore may be incapable of reducing flicker sufficiently to prevent a significant or serious flicker problem.

### SUMMARY

One aspect of embodiments of the present invention relate to provide an LED lamp, such as a G8 LED lamp or LED light that has improved heat dissipation and lower temperature during operation than comparative G8 LED lamps. Comparative LED lamps exhibit high failure rate and short service life due, in part, to poor heat dissipation function and high temperature during operation.

According to one embodiment of the present invention, a light emitting diode (LED) lamp includes: a housing; an thermally-conductive circuit board mounted inside the housing; a plurality of light emitting diodes (LEDs) mounted on the thermally-conductive circuit board; a plurality of pins arranged in the housing and electrically connected to the thermally-conductive circuit board; and a driving circuit mounted on the thermally-conductive circuit board, the driving circuit including a first heat-generating electronic element and a second heat-generating electronic element located on opposite surfaces of the thermally-conductive circuit board.

The opposite surfaces of the thermally-conductive circuit board may include a first surface and a second surface, the plurality of LEDs may be mounted on the first surface of the thermally-conductive circuit board, the first heat-generating electronic element of the driving circuit may include a driver transistor mounted to the first surface of the thermally-conductive circuit board, and the second heat-generating electronic element of the driving circuit may include a driving chip mounted on the second surface of the thermally-conductive circuit board.

The driving circuit may further include a through-hole capacitor mounted to the thermally-conductive circuit board, and the through-hole capacitor is on the second surface of the thermally-conductive circuit board.

The pins may extend from a bottom portion of the thermally-conductive circuit board, and the through-hole capacitor may be disposed in a top portion of the thermally-conductive circuit board above the driving chip.

The through-hole capacitor may include a plurality of conductive leads electrically connecting the through-hole capacitor to the thermally-conductive circuit board.

The through-hole capacitor may include a body having a height and a width, the height being greater than the width, the conductive leads extending from the body along a direction of the height of the body, and the conductive leads may be bent such that the direction of the height of the body is substantially parallel to the surfaces of the thermally-conductive circuit board.

The pins may extend from a bottom portion of the thermally-conductive circuit board, the plurality of LEDs may be mounted in a top portion of the thermally-conductive circuit board, and the driver transistor may be mounted below the plurality of LEDs.

The plurality of LEDs may be mounted on an upper end of the thermally-conductive circuit board in one or more rows.

The plurality of LEDs may include at least eight light emitting diodes (LEDs).

The thermally-conductive circuit board may be an aluminum-based circuit board.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a perspective view of an LED lamp according to one embodiment of the present invention.

FIG. 2 is an exploded view of an LED lamp according to one embodiment of the present invention.

FIG. 3 is a front view of an LED lamp according to one embodiment of the present invention.

FIG. 4 is a cross-sectional view of the LED lamp according to one embodiment of the present invention along the line A-A shown in FIG. 3.

FIG. 5 is a front view of a thermally-conductive circuit board according to one embodiment of the present invention.

FIG. 6 is a rear view of a thermally-conductive circuit board according to one embodiment of the present invention.

FIG. 7 is a cross-sectional view of the thermally-conductive circuit board according to one embodiment of the present invention along the line B-B shown in FIG. 6.

### DETAILED DESCRIPTION

In the following detailed description, only certain exemplary embodiments of the present invention are shown and described, by way of illustration. As those skilled in the art would recognize, the invention may be embodied in many different forms and should not be construed as being limited to the embodiments set forth herein. Also, in the context of the present application, when an element is referred to as being “on” another element, it can be directly on the other element or be indirectly on the other element with one or more intervening elements interposed therebetween.

When contrasted with comparative light emitting diode (LED) lamps, various aspects of embodiments of the present invention relate to differentiating features.

According to one embodiment of the present invention, a LED lamp (or LED light bulb, e.g., a G8 LED lamp or G8 LED light bulb) includes a housing, a thermally-conductive circuit board (e.g., a thermally conductive printed circuit board that includes a thermally conductive base layer, such as a metal base layer, and a layer of thermally conductive dielectric material that transfers heat to the base layer, where the metal base layer may be made of aluminum, such as in an aluminum-based circuit board), a plurality of light emitting diodes (LEDs or LED packages such as a LED in a surface mount package), and pins (e.g., for supplying external power). In some embodiments, the thermally-conductive circuit board is an aluminum-based circuit board. The thermally-conductive circuit board is mounted inside the housing, the plurality of LEDs are mounted on one surface of the thermally-conductive circuit board, the pins are arranged in the housing and electrically connected to the thermally-conductive circuit board; a driving circuit is disposed on the thermally-conductive circuit board, heat-generating electronic elements in the driving circuit are separately soldered on different (e.g., opposite) surfaces (or sides) of the thermally-conductive circuit board such that the heat-generating electronic elements are not concentrated on the same surface of the thermally-conductive circuit board and such that the heat sources are not concentrated together, thus facilitating and improving (or optimizing) the heat dissipation of LED lamps according to embodiments of the present invention. As a result of the improved heat dissipation, when the G8 LED lamp is turned on (e.g., operated), the overall temperature thereof will not be very high, which prolongs the service life and reduces the failure rate of a G8 LED lamp according to embodiments of the present invention.

While aspects of embodiments of the present invention will be described herein with reference to an example G8-type LED lamp, embodiments of the present invention are not limited thereto and may also be applied to LED lamps having similar shapes (e.g., LED lamps having bi-pin bases) and sizes (e.g., small lamps).

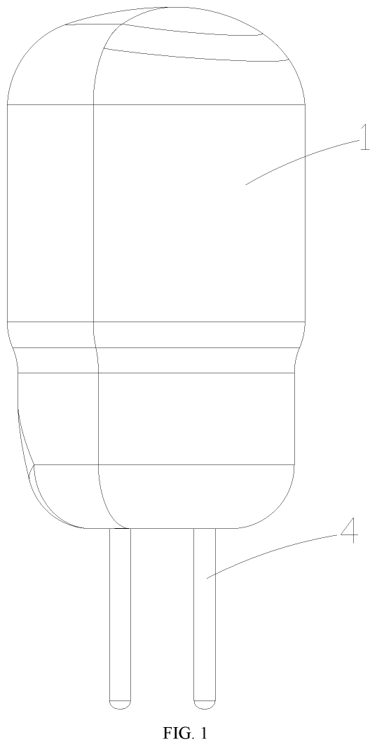

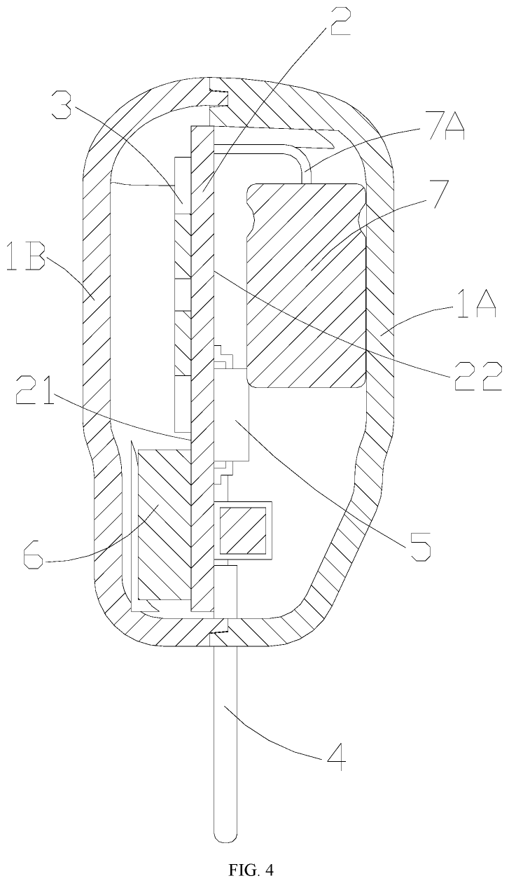

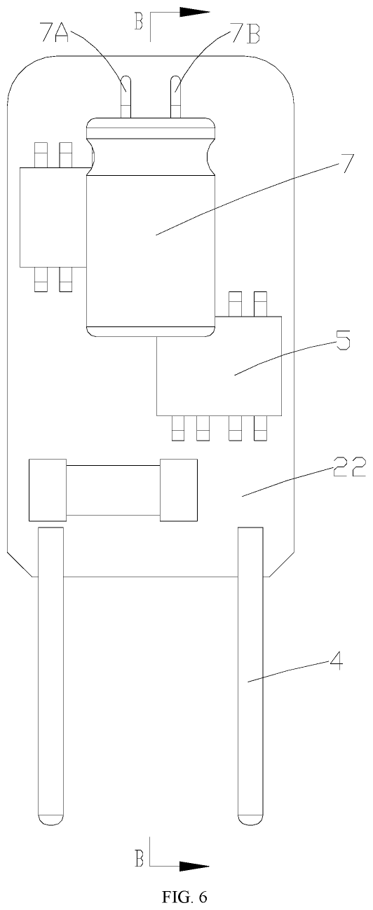

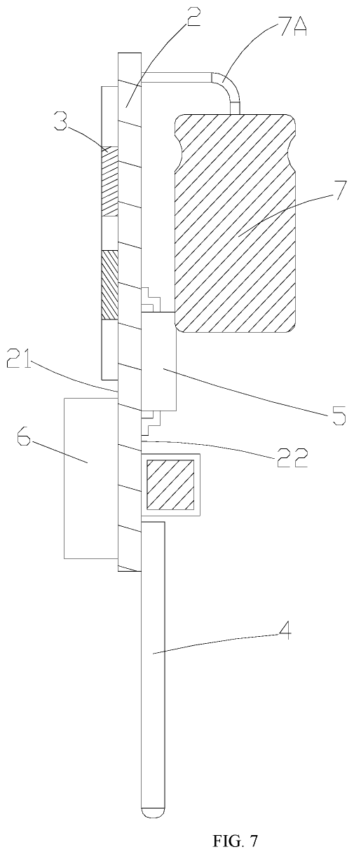

As shown in FIGS. 1 through 7, an LED lamp according to one embodiment of the present invention includes a housing 1, a thermally-conductive circuit board 2, a plurality of light emitting diodes (LEDs) 3, and pins 4, in which the thermally-conductive circuit board 2 is mounted inside (or within) the housing 1. The plurality of LEDs 3 are mounted on one surface of the thermally-conductive circuit board 2 (e.g., the LEDs 3 may be surface mount LEDs mounted to the surface of the thermally-conductive circuit board 2). The pins 4 are arranged in the housing 1 and are electrically connected to the thermally-conductive circuit board 2 (e.g., in instances where the LED lamp takes alternating current or AC input power, one of the pins 4 is electrically connected to a live line of the thermally-conductive circuit board 2 and another of the pins 4 is electrically connected to a neutral or ground line of the thermally-conductive circuit board 2). In addition, a driving circuit is disposed on (e.g., mounted on) the thermally-conductive circuit board 2, where heat-generating electronic elements (or electronic components) of the driving circuit are mounted on (e.g., soldered on) different surfaces (e.g., opposite surfaces or opposite sides) of the thermally-conductive circuit board 2. The heat-generating electronic elements are separately soldered thereon and are not concentrated on the same surface of the thermally-conductive circuit board (e.g., the heat-generating electronic components are soldered on different or opposite surfaces of the thermally-conductive circuit board 2), such that the heat sources are not concentrated together. As such, the heat dissipation is facilitated in LED lamps according to embodiments of the present invention, and is improved over comparative LED lamps. Accordingly, when using an LED lamp (e.g., a G8 LED lamp) according to embodiments of the present invention, the overall temperature thereof will not be very high, which can help reduce the failure rate of LED lamps (e.g., the G8 LED lamp) and thereby prolong its service life.

The housing 1 in the embodiment described above is a transparent housing made of a plastic material that transmits the light emitted by the LEDs 3 such that the housing 1 does not substantially block the light emitted from the LEDs 3.

In some embodiments, the housing 1 described above includes a first housing 1A and a second housing 1B, wherein the first housing 1A and the second housing 1B are attached together (e.g., friction fit, with interlocking tabs, and/or with an adhesive), and the thermally-conductive circuit board 2 is mounted on the first housing 1A. As such, according to some embodiments of the present invention, the structure of the housing 1 and the thermally-conductive circuit board 2 is simple and the assembly is convenient.

The thermally-conductive circuit board 2 of the embodiment described above includes a first surface 21 and a second surface 22 opposite the first surface 21 (e.g., the first surface or first side 21 and the second surface or second side 22 are the two largest planar surfaces of the thermally-conductive circuit board 2 and are parallel to one another and face in opposite directions). The driving circuit includes a driving chip 5 and a driver transistor 6 (e.g., a metal-oxide-semiconductor field effect transistor (MOSFET) or metal-oxide-silicon (MOS) transistor). The driver transistor 6 is soldered to the first surface 21 of the thermally-conductive circuit board 2 (the plurality of LEDs 3 are also mounted on the first surface 21 of the thermally-conductive circuit board 2). The driving chip 5 is mounted (e.g., soldered) on the second surface 22 of the thermally-conductive circuit board 2. In some embodiments, the driving chip 5 and the driver transistor 6 are the main heat-generating electronic elements of the driving circuit, and therefore the driving chip 5 and the driver transistor 6 are separately soldered such that they are on opposite surfaces of the thermally-conductive circuit board 2 (e.g., not on the same surface of the thermally-conductive circuit board 2), and the two heat sources are not be concentrated together, which thereby facilitates and improves the dissipation of heat from the LED lamp.

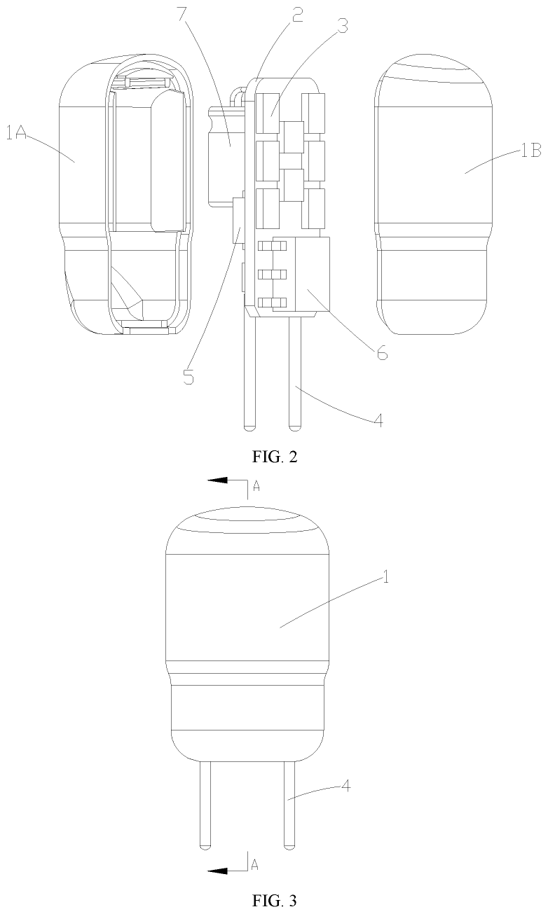

In the embodiments depicted in FIGS. 2, 4, 6, and 7, a through-hole capacitor 7 (or lead-type capacitor or in-line capacitor) is connected to (e.g., plugged in to) the thermally-conductive circuit board 2 described above, where the through-hole capacitor 7 is on the second surface 22 (e.g., a body portion of the through-hole capacitor 7 is facing the second surface 22) where the driving chip 5 is located. (However, embodiments of the present invention are not limited thereto. For example, in some embodiments the driving chip 5 is located, with the LEDs 3, on the first surface 21 of the thermally-conductive circuit board 2, and the driver transistor 6 is located, with the through-hole capacitor 7, on the second surface 22 of the thermally-conductive circuit board 2.) The through-hole capacitor 7 is used (e.g., instead of a chip capacitor) to make the electronic component assembly process of the thermally-conductive circuit board 2 easier and to save space or reduce the size of the lamp. In more detail, a chip-type capacitor is typically a surface-mount component where the base of the body of the chip-type capacitor can only be mounted flush against the surface of a circuit board. As a result, the body of the chip-type capacitor extends in a direction perpendicular to the circuit board 2. Increasing the capacitance of such a chip-type capacitor may therefore result in a larger area of the circuit board 2 being occupied by the chip-type capacitor, the chip-type capacitor extending farther along a direction perpendicular to the circuit board 2, or both. Therefore, space constraints on the circuit board 2 and size constraints of the housing 1 may limit the physical size of a chip-type capacitor used in an LED lamp, and may therefore also limit a maximum capacitance of such a capacitor. This, in turn, may result in a capacitor that is incapable of reducing flicker sufficiently to prevent a significant or serious flicker problem in the light emitted by the LEDs 3 because its capacitance is too small to smooth driving.

In contrast, a through-hole capacitor 7 (or lead-type capacitor) includes conductive leads 7A and 7B that connect the body of the through-hole capacitor 7 to the circuit board (e.g., to solder pads of through-holes of the thermally-conductive circuit board 2). As a result, using a through-hole or lead-type capacitor in accordance with embodiments of the present invention generally requires less area on the circuit board than using a chip-type capacitor (e.g., the area required by a lead-type capacitor is merely the size of the through-holes and solder pads on the circuit board, whereas a chip-type capacitor may occupy an area equal to greater than the cross-sectional size of its body). In addition, as shown in FIGS. 2, 4, 6, and 8, in some embodiments, the conductive leads 7A and 7B of the through-hole capacitor 7 allow the body of the capacitor to be spaced away from the circuit board, and the conductive leads 7A and 7B can also be bent such that the height of the body of the through-hole capacitor 7 (or the body of the lead-type capacitor) is oriented substantially parallel to the circuit board rather than perpendicular to the circuit board.

Electrolytic through-hole capacitors generally have a cylindrical body where the conductive leads extend from one end of the cylindrical body in a direction parallel to the axis of the cylinder. Generally, the height of the cylindrical body along the axial direction is larger than a width of the cylindrical body (e.g., a direction perpendicular to axis of the cylinder or the diameter of the cylindrical body). Therefore, bending the conductive leads allows the larger height (e.g., axial) dimension of the capacitor to be oriented to be parallel with the first surface 21 and the second surface 22 of the circuit board 2 and for the shorter width dimension of the capacitor (e.g., the diameter of the cylindrical body or the dimension perpendicular to the axis of the cylindrical body) to be perpendicular to the first surface 21 and the second surface 22 of the circuit board 2, thereby allowing the overall dimensions or the volume of the housing 1 to be smaller, while allowing capacitors having larger capacitances to be used, such as a capacitor having a capacitance sufficiently large to substantially prevent flicker of the LEDs 3. In addition, bending the conductive leads 7A and 7B of the through-hole capacitor 7 allows the body of the capacitor to be placed over other components on the circuit board (e.g., a line perpendicular to the plane of the circuit board 2 may intersect with the body of the through-hole capacitor 7 as well as other components such as the driver chip 5 and/or the LEDs 3.

In some embodiments, the through-hole capacitor 7 is (or includes) a through-hole electrolytic capacitor. The use of through-hole electrolytic capacitors allows for higher capacitances than using chip-type electrolytic capacitors, thereby substantially and effectively reducing (e.g., smoothing) the flicker problem of LEDs.

As shown in FIGS. 2, 4, 5, and 7, in some embodiments, the driver transistor 6 described above is soldered on the same surface of the thermally-conductive circuit board 2 as the LEDs 3 (e.g., first surface 21). For example, considering the pins 4 to extend from a lower end of the thermally-conductive circuit board and the LEDs 3 to mounted in an upper end of the thermally-conductive circuit board 2 opposite the lower end, the driver transistor 6 is mounted below the LEDs 3 in a lower end of the thermally-conductive circuit board. Thus, the position of the thermally-conductive circuit board 2 is efficiently utilized, so that the structure of the LED lamp according to embodiments of the present invention is more compact.

Similarly, as shown in FIGS. 2, 4, 6, and 7, in some embodiments, the through-hole capacitor 7 is located in the upper end of the thermally-conductive circuit board (e.g., opposite the lower end from which the pins 4 extend), above the driving chip 5, thus the position of the thermally-conductive circuit board 2 is efficiently utilized, so that the structure of the LED lamp according to embodiments of the present invention is made more compact.

In some embodiments, the plurality of LEDs 3 described above are mounted in a three-row arrangement on an upper end of the thermally-conductive circuit board 2 (e.g., away from the lower end of the thermally-conductive circuit board 2 from which the pins 4 extend), which appropriately arranges the LEDs 3 to make the structure of the LED lamp according to embodiments of the present invention more compact.

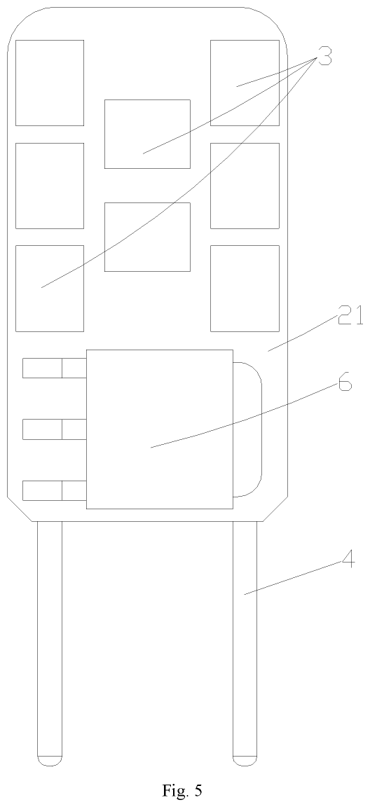

As shown in FIGS. 2 and 5, in some embodiments, at least eight LEDs 3 are provided on the thermally-conductive circuit board 2 described above to ensure the brightness of the LED lamp according to embodiments of the present invention (e.g., a G8 LED lamp).

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A light emitting diode (LED) lamp comprising:
a housing;
a thermally-conductive circuit board mounted inside the housing;
a plurality of light emitting diodes (LEDs) mounted on the thermally-conductive circuit board;
a plurality of pins arranged in the housing and electrically connected to the thermally-conductive circuit board; and
a driving circuit mounted on the thermally-conductive circuit board, the driving circuit comprising a first heat-generating electronic element and a second heat-generating electronic element located on opposite surfaces of the thermally-conductive circuit board.

2. The LED lamp of claim 1, wherein the surfaces of the thermally-conductive circuit board comprise a first surface and a second surface,
wherein the plurality of LEDs are mounted on the first surface of the thermally-conductive circuit board,
wherein the first heat-generating electronic element of the driving circuit comprises a driver transistor mounted to the first surface of the thermally-conductive circuit board, and
wherein the second heat-generating electronic element of the driving circuit comprises a driving chip mounted on the second surface of the thermally-conductive circuit board.

3. The LED lamp of claim 2, wherein the driving circuit further comprises a through-hole capacitor mounted to the thermally-conductive circuit board, and
wherein the through-hole capacitor is on the second surface of the thermally-conductive circuit board.

4. The LED lamp of claim 3, wherein the pins extend from a bottom portion of the thermally-conductive circuit board, and
wherein the through-hole capacitor is disposed in a top portion of the thermally-conductive circuit board above the driving chip.

5. The LED lamp of claim 3, wherein the through-hole capacitor comprises a plurality of conductive leads electrically connecting the through-hole capacitor to the thermally-conductive circuit board.

6. The LED lamp of claim 5, wherein the through-hole capacitor comprises a body having a height and a width, the height being greater than the width, the conductive leads extending from the body along a direction of the height of the body, and
wherein the conductive leads are bent such that the direction of the height of the body is substantially parallel to the surfaces of the thermally-conductive circuit board.

7. The LED lamp of claim 2, wherein the pins extend from a bottom portion of the thermally-conductive circuit board,
wherein the plurality of LEDs are mounted in a top portion of the thermally-conductive circuit board, and
wherein the driver transistor is mounted below the plurality of LEDs.

8. The LED lamp of claim 1, wherein the plurality of LEDs are mounted on an upper end of the thermally-conductive circuit board in one or more rows.

9. The LED lamp of claim 8, wherein the plurality of LEDs comprise at least eight light emitting diodes (LEDs).

10. The LED lamp of claim 1, wherein the thermally-conductive circuit board is an aluminum-based circuit board.
